(19) United States
(12) Patent Application Publication
(10) Pub. No.: US 2009/0294885 A1
(43) Pub. Date: Dec. 3, 2009

(54) Silicon Nanoparticle Embedded Insulating Film Photodetector

(76) Inventors: Pooran Chandra Joshi, Vancouver, WA (US); Hao Zhang, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/129,434

(22) Filed: May 29, 2008

(51) Int. Cl. H01L 31/00; H01L 21/00

(52) U.S. Cl. 257/432; 438/63; 257/E31.001; 257/E21.001

(57) ABSTRACT

A photodetector is provided with a method for fabricating a semiconductor nanoparticle embedded Si insulating film for photo-detection applications. The method provides a bottom electrode and introduces a semiconductor precursor and hydrogen. A thin-film is deposited overlying the substrate, using a high density (HD) plasma-enhanced chemical vapor deposition (PECVD) process. As a result, a semiconductor nanoparticle embedded Si insulating film is formed, where the Si insulating film includes either N or C elements. For example, the Si insulating film may be a non-stoichiometric SiO_{X}N_{Y} thin-film, where (X+Y<2 and Y>0), or SiC_{X}, where X<1. The semiconductor nanoparticles are either Si or Ge. Following the formation of the semiconductor nanoparticle embedded Si insulating film, an annealing process is performed.

### BACKGROUND OF THE INVENTION

1. Field of the Invention

This invention generally relates to the fabrication of integrated circuit (IC) photodetectors, and more particularly, to a photodetector made from a silicon (Si) nanoparticle embedded insulating film, using a high-density plasma-enhanced chemical vapor deposition process.

2. Description of the Related Art

The fabrication of integrated optical devices involves the deposition of materials with suitable optical characteristics such as absorption, transmission, and spectral response. Thin-film fabrication techniques can produce diverse optical thin films, which are suitable for the production of large area devices at high throughput and yield. Some optical parameters of importance include refractive index and the optical band-gap, which dictate the transmission and reflection characteristics of the thin film.

Typically, bilayer or multilayer stack thin-films are required for the fabrication of optical devices with the desired optical effect. Various combinations of the metal, dielectric, and/or semiconductor layers are also used to form multilayer films with the desired optical characteristics. The selection of the material depends on the target reflection, transmission, and absorption characteristics. While a single layer device would obviously be more desirable, no single thin-film material has been able to provide the wide range of optical dispersion characteristics required to get the desired optical absorption, band-gap, refractive index, reflection, or transmission over a wide optical range extending from ultraviolet (UV) to far infrared (IR) frequencies.

Silicon is the material of choice for the fabrication of optoelectronic devices because of well-developed processing technology. However, the indirect band-gap makes it an inefficient material for optoelectronic devices. Over the years, various R&D efforts have focused on tailoring the optical function of Si to realize Si-based optoelectronics. The achievement of efficient room temperature light emission from the crystalline silicon is a major step towards the achievement of fully Si-based optoelectronics.

At present, the Si thin film-based photodetectors operating at wavelengths shorter than 850 nm are attractive for low cost, highly integrated CMOS devices. Si is an indirect bandgap semiconductor with limited speed-responsivity performance, but it is still useful for detection in UV-VIS (visible)-NIR (near-IR) spectrum. However, the indirect bandgap of Si limits the critical wavelength of Si to 1.12 μm, beyond which its absorption goes to zero, making it insensitive to two primary telecommunication wavelengths of 1.30 and 1.55 μm. An additional issue with Si based photo-detectors is the dark current limiting the signal-to-noise ratio (SNR), and the thermal instability at operating temperatures higher than 50° C.

The fabrication of stable and reliable optoelectronic devices requires Si nanocrystals with high photoluminescence (PL) and electroluminescence (EL) quantum efficiency. One approach that is being actively pursued for integrated optoelectronic devices is the fabrication of SiOₓ (x≦2) thin films with embedded Si nanocrystals. The luminescence due to recombination of the electron-hole pairs confined in Si nanocrystals depends strongly on the nanocrystal size. The electrical and optical properties of the nanocrystalline Si embedded SiOₓN_{y} thin films depend on the size, concentration, and distribution of the Si nanocrystals. Various thin-film deposition techniques such as sputtering and plasma-enhanced chemical vapor deposition (PECVD), employing a capacitively-coupled plasma source, are being investigated for the fabrication of stable and reliable nanocrystalline Si thin films, which are also referred to herein as nanocrystalline Si embedded insulating thin films.

However, conventional PECVD and sputtering techniques have the limitations of low plasma density, inefficient power coupling to the plasma, low ion/neutral ratio, and uncontrolled bulk, and interface damage due to high ion bombardment energy. Therefore, the oxide films formed from a conventional capacitively-coupled plasma (CCP) generated plasma may create reliability issues due to the high bombardment energy of the impinging ionic species. It is important to control or minimize any plasma-induced bulk or interface damage. However, it is not possible to efficiently control the ion energy using the radio frequency (RF) power of CCP generated plasma. Any attempt to enhance the reaction kinetics by increasing the applied power results in increased bombardment of the deposited film, creating a poor quality films with a high defect concentration. Additionally, the low plasma density associated with these types of sources (˜1×10⁸-10⁹ cm⁻³) leads to limited reaction possibilities in the plasma and on the film surface, inefficient generation of active radicals and ions for enhanced process kinetics, inefficient oxidation, and process and system induced impurities, which limits their usefulness in the fabrication of low-temperature electronic devices.

A deposition process that offers a more extended processing range and enhanced plasma characteristics than conventional plasma-based techniques, such as sputtering, PECVD, etc., is required to generate and control the particle size for PL and electroluminescent (EL) based device development. A process that can enhance plasma density and minimize plasma bombardment will ensure the growth of high quality films without plasma-induced microstructural damage. A process that can offer the possibility of controlling the interface and bulk quality of the films independently will enable the fabrication of high performance and high reliability electronic devices. A plasma process that can efficiently generate the active plasma species, radicals and ions, will enable noble thin film development with controlled process and property control.

For the fabrication of high quality SiOx thin films, the oxidation of a grown film is also critical to ensure high quality insulating layer across the nanocrystalline Si particles. A process that can generate active oxygen radicals at high concentrations will ensure the effective passivation of the Si nanoparticles (nc-Si) in the surrounding oxide matrix. A plasma process that can minimize plasma-induced damage will enable the formation of a high quality interface that is critical for the fabrication of high quality devices. Low thermal budget efficient oxidation and hydrogenation processes are critical and will be significant for the processing of high quality optoelectronic devices. The higher temperature thermal processes can interfere with the other device layers and they are not suitable in terms of efficiency and thermal budget, due to the lower reactivity of the thermally activated species. Additionally, a plasma process which can provide a more complete solution and capability in terms of growth/deposition of novel film structures, oxidation, hydrogenation, particle size creation and control, and independent control of plasma density and ion energy, and large area processing is desired for the development of high performance optoelectronic devices. Also, it is important to correlate the plasma process with the thin film properties as the various plasma parameters dictate the thin film properties and the desired film quality depends on the target application. Some of the key plasma and thin-film characteristics that depend on the target application are deposition rate, substrate temperature, thermal budget, density, microstructure, interface quality, impurities, plasma-induced damage, state of the plasma generated active species (radicals/ions), plasma potential, process and system scaling, and electrical quality and reliability. A correlation among these parameters is critical to evaluate the film quality as the process map will dictate the film quality for the target application. It may not be possible to learn or develop thin-films by just extending the processes developed in low density plasma or other high-density plasma systems, as the plasma energy, composition (radical to ions), plasma potential, electron temperature, and thermal conditions correlate differently depending on the process map.

Low temperatures are generally desirable in liquid crystal display (LCD) manufacture, where large-scale devices are formed on transparent glass, quartz, or plastic substrate. These transparent substrates can be damaged when exposed to temperatures exceeding 650 degrees C. To address this temperature issue, low-temperature Si oxidation processes have been developed. These processes use a high-density plasma source such as an inductively coupled plasma (ICP) source, and are able to form Si oxide with a quality comparable to 1200 degree C. thermal oxidation methods.

It would be advantageous if the benefits realized with high-density plasma Si-containing films could be used in the fabrication of photodetectors made from semiconductor nanoparticle embedded Si insulating films. As used herein, a Si insulating film is an insulating film with Si as one of the constituent elements.

### SUMMARY OF THE INVENTION

The present invention describes a photodetector made from semiconductor nanoparticles (e.g., nc-Si) embedded Si insulating films, such as SiOₓN_{y} thin films. The nc-semiconductor particles embedded in the insulating matrix generate high photo-current at low reverse biases. The high SNR of the nc-semiconductor embedded Si insulating thin films overcome the limitations of conventional Si and wide-band gap semiconductor-based photodetectors. The photoconduction in the nc-semiconductor embedded Si insulating thin films makes possible metal-film-metal (MFM) photodetectors, which offer the unique advantages of high sensitivity-bandwidth product, low capacitance, and ease of integration. The photo-response and the current conduction in nc-semiconductor embedded Si insulating thin films can be controlled over a broad range by varying the particle size and distribution, particle density, inter-particle distance, optical dispersion, and film composition. In fabricating the semiconductor nanoparticles embedded Si insulating films, a low temperature, high density plasma (HDP)-based process is described.

Accordingly, a method is provided for fabricating a semiconductor nanoparticle embedded Si insulating film for photo-detection applications. The method provides a bottom electrode and introduces a semiconductor precursor and hydrogen. A thin-film is deposited overlying the substrate, using a high density (HD) plasma-enhanced chemical vapor deposition (PECVD) process. As a result, a semiconductor nanoparticle embedded Si insulating film is formed, where the Si insulating film includes either N or C elements. For example, the Si insulating film may be a non-stoichiometric SiO_{X}N_{y} thin-film, where (X+Y<2 and Y>0), or SiC_{X}, where X<1. The semiconductor nanoparticles are either Si or Ge.

In one aspect, the method heats the substrate to a temperature of less than about 400° C., and the thin-film HD PECVD process uses a plasma concentration of greater than 1×10¹¹ cm⁻³, with an electron temperature of less than 10 eV. Following the formation of the semiconductor nanoparticle embedded Si insulating film, an annealing process is performed. In one aspect, a heat source is used having a radiation wavelength of about 200 to 600 nanometers (nm) or 9 to 11 micrometers. In another aspect, an HD plasma treatment is performed in an H₂ atmosphere, using a substrate temperature of less than 400° C., hydrogenating the semiconductor nanoparticle embedded Si insulating film.

Additional details of the above-described method and a photodetector employing a semiconductor nanoparticle embedded insulating film are presented below.

### BRIEF DESCRIPTION OF THE DRAWINGS

FIG. 1 is a partial cross-sectional view of a photodetector employing a semiconductor nanoparticle embedded insulating film.

FIG. 2 is a schematic block diagram depicting the photodetector of FIG. 1 under bias, in a horizontal configuration.

FIG. 3 is a schematic block diagram depicting the photodetector of Fig. under bias, in a vertical configuration.

FIG. 4 is a schematic drawing of a high-density plasma (HDP) system with an inductively coupled plasma source.

FIG. 5 depicts a setup used for photo-response measurements.

FIG. 6 is a graph depicting photo-conduction characteristics of a 200 nm-thick film deposited on an n⁺ silicon substrate.

FIGS. 7A and 7B are graphs depicting the effect of the film thickness and Si substrate doping on the photo-response measurements.

FIGS. 8A and 8B are graphs depicting the effect of temperature on current using films deposited on an n⁺ substrate.

FIG. 9A is a graph depicting SNR for a 50 nm-thick film deposited on an n⁺ silicon substrate.

FIGS. 9B and 9C illustrate some optical dispersion characteristics of nc-Si embedded SiOₓ thin films.

FIGS. 10A through 10C illustrate the PL spectrum of some HDP processed nc-Si embedded SiOₓ thin films covering the visible part of the spectrum.

FIG. 11 is a flowchart illustrating a method for fabricating a semiconductor nanoparticle embedded Si insulating film for photo-detection applications.

### DETAILED DESCRIPTION

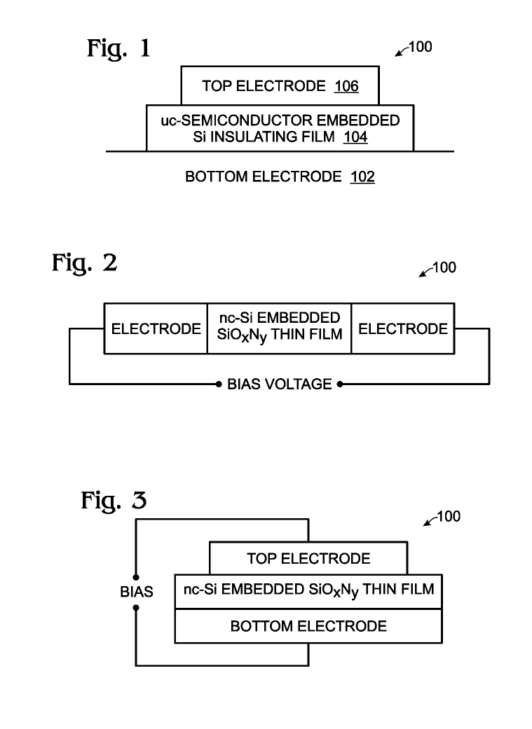

FIG. 1 is a partial cross-sectional view of a photodetector employing a semiconductor nanoparticle embedded insulating film. The photodetector 100 comprises a bottom electrode 102, which may be a doped semiconductor, metal, or polymer. A semiconductor nanoparticle embedded Si insulating film 104 overlies the bottom electrode 102. The insulating film includes either N or C elements. In one aspect, the Si insulating film 104 is a non-stoichiometric SiO_{X1}N_{Y1} thin-film, where (X1+Y1<2 and Y1>0). In another aspect, the Si insulating film 104 is a SiC_{X} thin film, where X<1.

The semiconductor nanoparticles embedded in the Si insulating film 104 have a diameter in the range of about 1 to 10 nanometers (nm), and are made from either Si or Ge. The semiconductor nanoparticle embedded Si insulating film 104 exhibits a spectral response in a wavelength range of about 200 nanometers (nm) to about 1600 nm. A transparent electrode 106, such an indium tin oxide (ITO) or a thin metal, overlies the insulating film.

The photo-conduction in nc-semiconductor embedded Si insulator thin films overcomes the major limitations of Si and wide hand gap (WBG) semiconductor-based photo-detectors, using charge generation and conduction by the nc-semiconductor particles in a dielectric matrix. The enhanced performance is due to various control variables which are not available with Si or WBG semiconductor-based photodetector (PD) devices whose characteristics are dominantly defined by the material characteristics.

The photodetector performance, spectral-response, and the electrical conduction of the nc-semiconductor embedded Si insulating thin films can be tuned over a wide range by varying the particle size and distribution, particle density, inter-particle distance, optical dispersion, film composition, and doping. The HDP technique is suitable for the fabrication of high performance thin films at low temperatures due to enhanced plasma characteristics (high plasma density, low plasma potential, and independent control of ion energy and density) compared to conventional plasma based techniques. The present invention describes a method for creating uniform particle distribution across the film thickness, irrespective of the thickness, which is not achievable by other approaches for nc-semiconductor particle formation such as ion implantation. While it is difficult to quantify uniform particle distribution effectively, the uniformity of distribution is a clear advantage associated with the in-situ creation of nc-Si particles, as compared to the Si ion implantation approach for nc-Si creation in an insulating matrix.

FIG. 2 is a schematic block diagram depicting the photodetector of FIG. 1 under bias, in a horizontal configuration.

FIG. 3 is a schematic block diagram depicting the photodetector of Fig. under bias, in a vertical configuration. The carrier generation and conduction from particle-to-particle through the insulating matrix permits controlled spectral responses and electrical conduction characteristics.

As explained in more detail below, and as presented in pending patent application NON-STOICHIOMETRIC SiNxOy OPTICAL FILTERS, invented by Joshi et al., filed Apr. 26, 2007, Ser. No. 11/789,947, Attorney Docket No. SLA8118, which is incorporated herein by reference, HDP plasma processed semiconductor nanoparticles embedded Si insulating thin films show a wide optical dispersion depending on the processing conditions. It is possible to vary the refractive index and the extinction constant of the films. In addition, the HDP plasma process enables the independent control of the n and k values, which can be successfully exploited for the fabrication of devices with wide process margins, and a significant reduction in process complexity and cost.

The selection of the thin films for optoelectronic applications depends on the optical, electrical, mechanical, and chemical properties. The selection of the fabrication technique and deposition process is equally important for the fabrication of high quality thin films. Various thin film characteristics such as microstructure, grain size, composition, density, defects and impurities, structural homogeneity, and interfacial characteristics are strongly influenced by the deposition technique and process parameters.

As used herein, a nc-Si embedded SiOₓN_{y} (x+y<2) thin film is also referred to as a non-stoichiometric SiO_{X}N_{Y} thin-film, where (X+Y<2 and Y>0). A non-stoichiometric SiO_{X}N_{Y} thin-film, as used herein, is understood to be a film with nanocrystalline (nc) Si particles, and may also be referred to as a Si-rich SiO_{X}N_{Y} thin-film. The term “non-stoichiometric” as used herein retains the meaning conventionally understood in the art as a chemical compound with an elemental composition that cannot be represented by a ratio of well-defined natural numbers and is, therefore, in violation of the law of definite proportions. Conventionally, a non-stoichiometric compound is a solid that is understood to include random defects, resulting in the deficiency of one element. Since the compound needs to be overall electrically neutral, the missing atom's charge requires compensation in the charge for another atom in the compound, by either changing the oxidation state, or by replacing it with an atom of a different element with a different charge. More particularly, the “defect” in a non-stoichiometric SiO_{X}N_{Y} involves nanocrystalline particles.

The HDP technique is suitable for the fabrication of high quality thin films due to high plasma density, low plasma potential, and independent control of plasma energy and density. The HDP technique is also attractive for the fabrication high quality films with minimal process or system induced impurity content. The HDP processed films exhibit superior bulk and interfacial characteristics due to minimal plasma induced structural damage and process-induced impurities, as compared to conventional plasma based deposition techniques such sputtering, ion beam deposition, capacitively-coupled plasma (CCP) source based PECVD, and hot-wire CVD. The present invention describes an HDP process for the creation of nano-semiconductor particles in Si insulating films in the as-deposited state. The nc-semiconductor particle concentration can be further enhanced by post-deposition annealing. The electrical conductivity, photo-response, photoluminescence (PL), and electroluminescence (EL) characteristics can be improved by defect passivation treatments. The HDP processed nc-semiconductor embedded Si insulating films have tunable optical dispersion characteristics which can be exploited for the fabrication of optoelectronic devices.

Another significant aspect of the nc-semiconductor embedded Si insulating films is significant PL emission in the visible part of the spectrum, which can be used for the fabrication of active optical devices exhibiting signal gain and wavelength tuning. The optical characteristics of the HDP processed thin films can be further tuned by doping suitable impurities to control the optical response extending on either side of the visible spectrum, i.e., deep UV to far IR. The HDP technique is also suitable for low temperature and low thermal budget defect passivation of the films for an enhanced electrical and optical response.

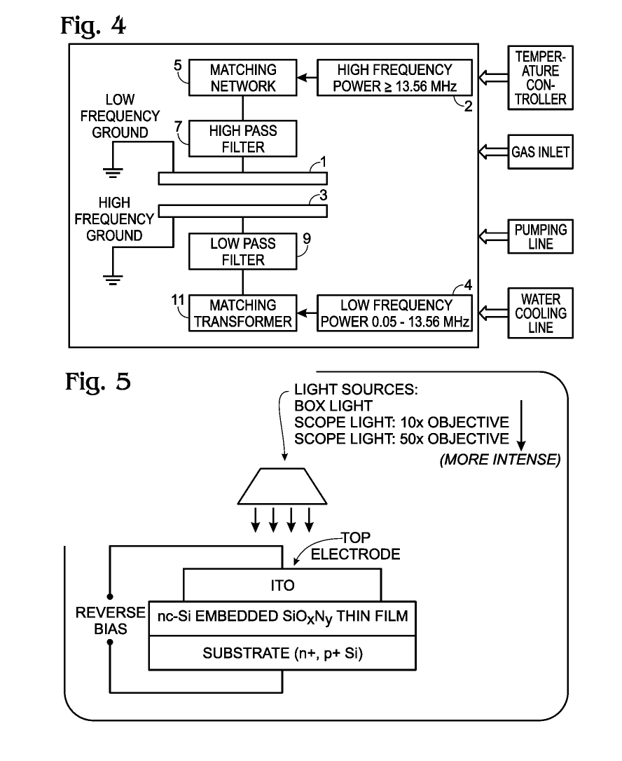

FIG. 4 is a schematic drawing of a high-density plasma (HDP) system with an inductively coupled plasma source. The top electrode 1 is driven by a high frequency radio frequency (RF) source 2, while the bottom electrode 3 is driven by a lower frequency power source 4. The RF power is coupled to the top electrode 1, from the high-density inductively coupled plasma (ICP) source 2, through a matching network 5 and high pass filter 7. The power to the bottom electrode 3, through a low pass filter 9 and matching transformer 11, can be varied independently of the top electrode 1. The top electrode power frequency can be in the range of about 13.56 to about 300 megahertz (MHz) depending on the ICP design. The bottom electrode power frequency can be varied in the range of about 50 kilohertz (KHz) to about 13.56 MHz, to control the ion energy. The pressure can be varied up to 500 mTorr. The top electrode power can be as great as about 10 watts per square-centimeter (W/cm²), while the bottom electrode power can be as great as about 3 W/cm².

One interesting feature of the HDP system is that there are no inductive coils exposed to the plasma, which eliminates any source-induced impurities. The power to the top and bottom electrodes can be controlled independently. There is no need to adjust the system body potential using a variable capacitor, as the electrodes are not exposed to the plasma. That is, there is no crosstalk between the top and bottom electrode powers, and the plasma potential is low, typically less than 20 V. System body potential is a floating type of potential, dependent on the system design and the nature of the power coupling.

The HDP tool is a true high-density plasma process with an electron concentration of greater than 1×10¹¹ cm⁻³, and the electron temperature is less than 10 eV. There is no need to maintain a bias differential between the capacitor connected to the top electrode and the system body, as in many high-density plasma systems and conventional designs such as capacitively-coupled plasma tools. Alternately stated, both the top and bottom electrodes receive RF and low frequency (LF) powers.

High quality stoichiometric SiOₓN_{y} (x+y=2) and nc-Si embedded SiOₓN_{y} (x+y<2) thin films can be processed by HDP techniques at process temperatures below 400° C. Some of the substrates that are suitable for integrated optical devices are Si, Ge, glass, quartz, SiC, GaN, SiₓGe₁₋ₓ. The HDP processed films can be doped in-situ by adding a dopant source gas or incorporating physical sputtering source in the chamber along with the high-density PECVD setup. The optical properties of the HDP processed films can also be modified by implanting dopant species. Some typical process conditions for the fabrication of stoichiometric SiOₓN_{y} (x+y=2) and nc-Si embedded SiOₓN_{y} (x+y<2) thin films by HD-PECVD technique are listed in Table 1.

TABLE 1
High-density plasma deposition of stoichiometric SiOₓN_{y}
(x + y = 2) and nc-Si embedded SiOₓN_{y} (x + y < 2) thin films

| | |
|---|---|
| Top Electrode Power | 13.56-300 MHz, up to 10 W/cm², |
| Bottom Electrode Power | 50 KHz-13.56 MHz, up to 3 W/cm² |
| Pressure | 1-500 mTorr |
| Si source | Any suitable Si precursor (SiH₄, Si₂H₆, |
| | TEOS, etc.) e.g.: SiH₄ |
| Oxygen Source | Any suitable source of oxygen: (O₂, O₃, |
| | NO, etc.) e.g.: N₂O, O₂ |
| Nitrogen Source | Any suitable source of nitrogen (NH₃, |
| | N₂, etc.) e.g.: N₂ |
| Inert Gases ion the plasma | Any suitable inert gas: Noble gases, |
| | N₂, etc. |
| nc-Si particle creation and | nc-Si particles: Silicon source + |
| defect passivation | Oxygen source + inert gases + H₂ |
| | Passivation: Source of hydrogen (NH₃, |
| | H₂, etc.) |
| Temperature | 25-400° C. |

FIG. 5 depicts a setup used for photo-response measurements. Photo-response measurements were conducted on nc-Si embedded SiOx thin films in a MOS-C configuration with transparent ITO as the top electrode. The light source for the measurements was a probe station microscope (50× objective) and a lamp hanging on the box. The photo-conduction measurements were performed on three different square electrodes with side dimensions of 100, 200, and 400 μm. The box light was effective in generating appreciable charge carriers in the films.

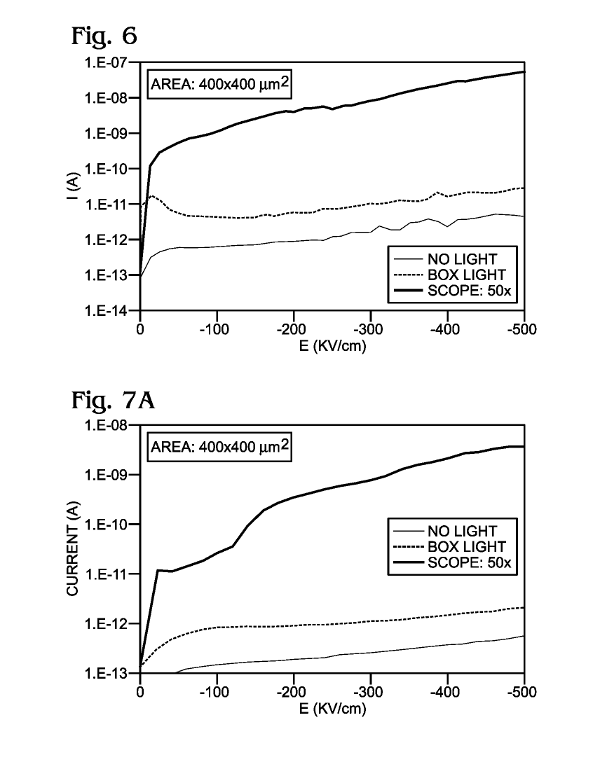

FIG. 6 is a graph depicting photo-conduction characteristics of a 200 nm-thick film deposited on an n⁺ silicon substrate. As shown, the reverse leakage current of the film was found to increase by an order of magnitude as a result of box light illumination, even though the source was more than 1 m away and the light was blocked by the objective. When illuminated by the light through a 50× objective, the current was found to increase by many orders of magnitude. The room temperature SNR ratio was greater than 1000 at an applied electric field of −500 kV/cm. When the light was turned off, the leakage current was found to instantly jump back to the dark current levels.

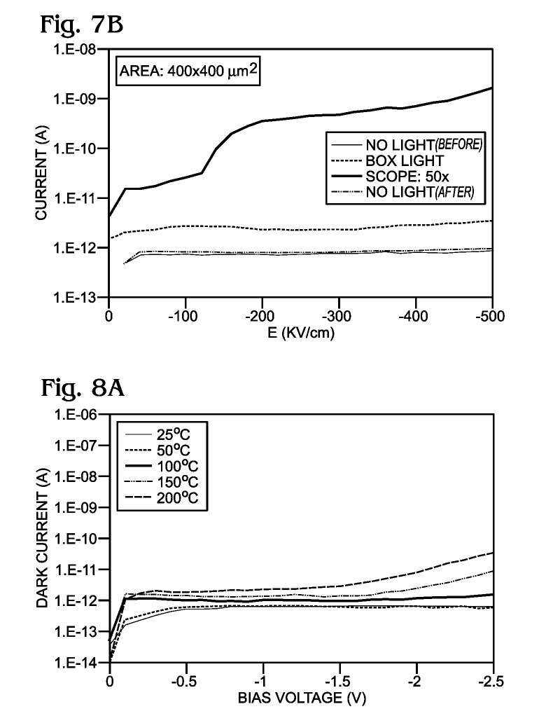

FIGS. 7A and 7B are graphs depicting the effect of the film thickness and Si substrate doping on the photo-response measurements. The photo-response of 50 nm-thick films, deposited on n⁺ (FIG. 7A) and p⁺ (FIG. 7B) Si substrates, was analyzed. As shown, the 50 nm-thick films exhibit high SNR on both n⁺ and p⁺ substrates, exceeding 1000 at an applied electric field of −500 kV/cm, when illuminated by a light through a 20× objective.

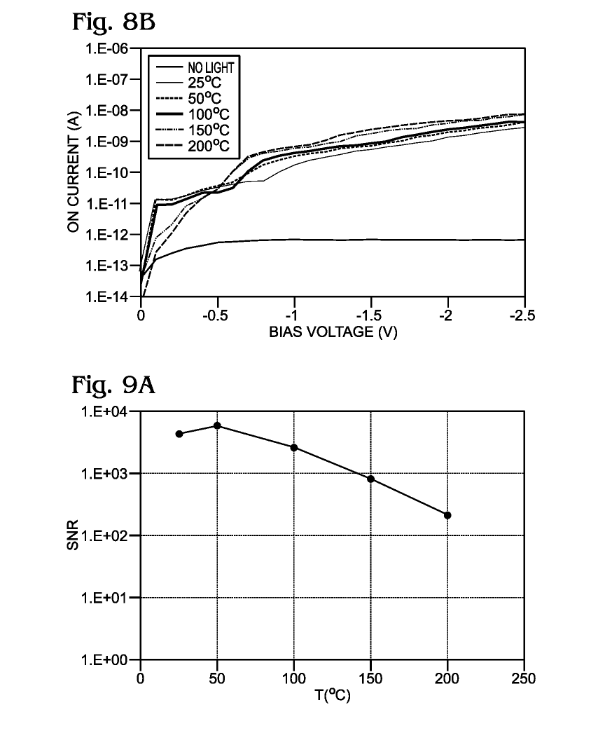

FIGS. 8A and 8B are graphs depicting the effect of temperature on current using films deposited on an n⁺ substrate. The photo-response was analyzed in the range of 25-200° C. for 50 and 200-nm-thick films. For a 50 nm-thick film, the dark current (FIG. 8A) was found to increase by less than two orders of magnitude, even at a measurement temperature of 200° C. The increase was found to be lower than a factor of 10, up to a measurement temperature of 100° C. The ON-current (FIG. 8B) was also found to increase with an increase in the measurement temperature. However, the increase was within an order of magnitude, up to a measurement temperature of 200° C.

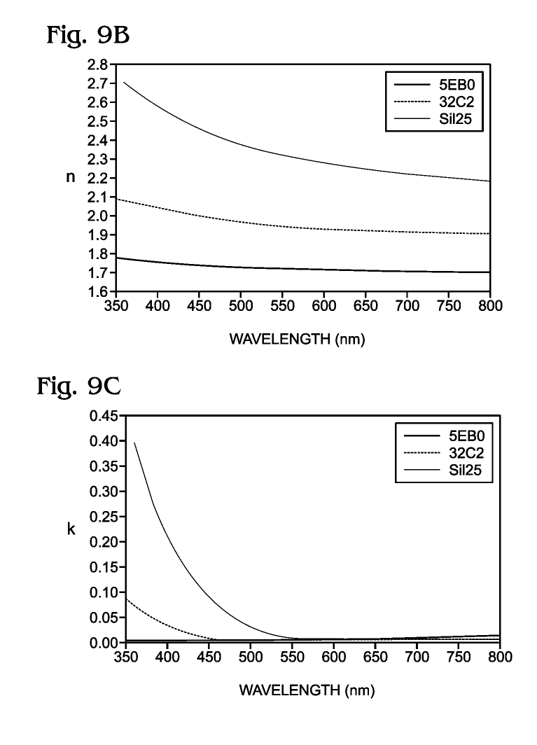

FIG. 9A is a graph depicting SNR for a 50 nm-thick film deposited on an n⁺ silicon substrate. The 50 nm-thick films show high SNR characteristics with stable dark current characteristics. The SNR ratio remains higher than 100, even at a measurement temperature of 200° C. The observed photo-response of the nc-Si embedded SiOₓ thin films offers significantly enhanced SNR and thermal stability over conventional Si photodiode based sensors.

FIGS. 9A and 9B illustrate some optical dispersion characteristics of nc-Si embedded SiOₓ thin films. It is possible to tune the refractive index and the extinction coefficient of the films independently. The independent control of the n and k values enables a better control of the optical transmission, reflection, and absorption characteristics for the design of novel optical and optoelectronic devices. The optical absorption edge of the films can also be effectively controlled by varying the thin film composition and the nc-Si particle size. The combination of the n, k dispersion, absorption edge, and PL/EL emission characteristics can be exploited for the fabrication of novel optical and optoelectronic devices with controlled optical response characteristics.

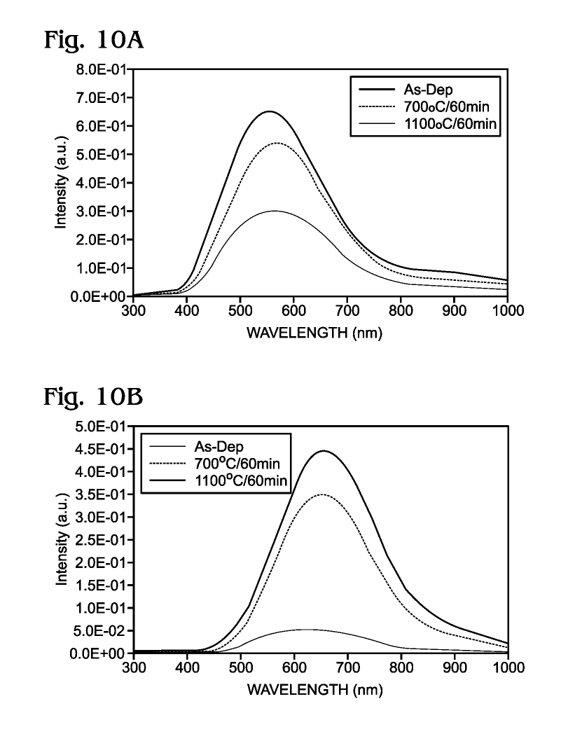

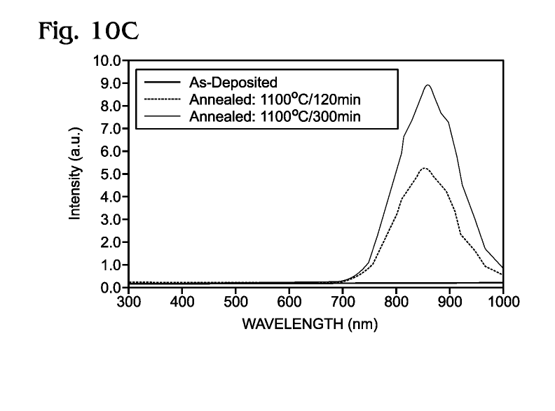

FIGS. 10A through 10C illustrate the PL spectrum of some HDP processed nc-Si embedded SiOₓ thin films covering the visible part of the spectrum. The emitted wavelength depends strongly on the particle size. The HDP plasma process is efficient in the controlling the particle size over a wide range covering the entire visible spectrum. The HDP process is effective in the creation of the nc-Si particles at a low process temperature of 300° C., as is evident in the appreciable PL signal. The PL emission intensity is significantly enhanced by post-deposition annealing treatment at higher temperatures, which is due to phase separation and quantum confinement effects. Additionally, the HDP technique is suitable for the low temperature and low thermal budget defect passivation.

To summarize, single or multilayer structures can be made using the above-described nc-Si embedded SiOₓN_{y} (x+y<2) thin films, with control over n, k, and wavelength emission in terms of film composition, annealing treatment, passivation, and nc-particle size control. Active waveguides can be formed capable of wavelength conversion and narrowing down the wavelength spectrum. Group IV, rare earth dopants can be added to the films for wavelength control. Optical gain and birefringence can be exploited for optoelectronic applications. Enhanced optical emission control over the emitted wavelength can be obtained by doping. The nc-Si embedded SiOₓN_{y} (x+y<2) thin films can be used with a wide range of other materials. For example, optical wave-guides can be integrated with PIN diode detectors. Also, nc-Si embedded thin films can be integrated with wide band-gap semiconductors or phosphors for enhanced light emission and control. Additional details of the fabrication processes can be found in a related pending patent application entitled, HIGH DENSITY PLASMA STOICHIOMETRIC SiOxNy FILMS, invented by Pooran Joshi et al., Ser. No. 11/698,623, filed on Jan. 26, 2007, Attorney Docket No. SLA8117, which is incorporated herein by reference.

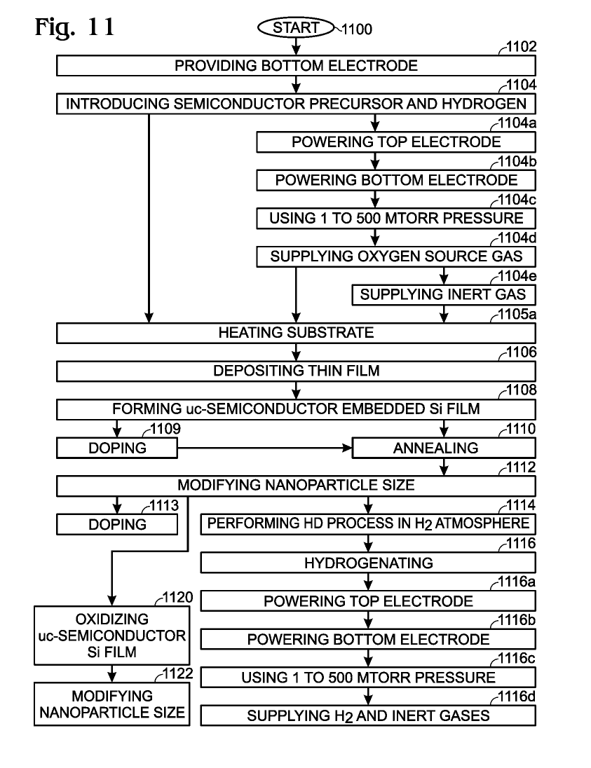

FIG. 11 is a flowchart illustrating a method for fabricating a semiconductor nanoparticle embedded Si insulating film for photo-detection applications. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1100.

Step 1102 provides a bottom electrode. Step 1104 introduces a semiconductor precursor and hydrogen. Step 1105a heats the substrate to a temperature of less than about 400° C. Optionally, higher temperatures may be used. Step 1106 deposits a thin-film overlying the substrate, using a HD PECVD process. In one aspect, the HD PECVD process uses an inductively coupled plasma (ICP) source. In another aspect, the HD PECVD process uses a plasma concentration of greater than 1×10¹¹ cm⁻³, with an electron temperature of less than 10 eV. Step 1108 forms a semiconductor nanoparticle embedded Si insulating film including either N or C elements. For example, the semiconductor nanoparticle embedded Si insulating film may be non-stoichiometric SiO_{X}N_{Y} thin-film, where (X+Y<2 and Y>0). The optical dispersion characteristics of the non-stoichiometric SiO_{X}N_{Y} thin-film films can also be tailored by varying the values of X and Y with respect to the thickness of the thin-film. Alternately, the semiconductor nanoparticle embedded Si insulating film may be SiC_{X}, where X<1. The semiconductor nanoparticles are either Si or Ge.

In one aspect, supplying the semiconductor precursor and hydrogen in Step 1104 includes supplying a precursor selected from a group consisting of SiₙH₂_{ⁿ⁺²} and GeₙH₂ₙ₊₂, where n varies from 1 to 4, SiHₓR₄₋ₓ where R is selected from a first group consisting of Cl, Br, and I, and where x varies from 0 to 3, and GeHₓR₄₋ₓ where R is selected from the first group (Cl, Br, or I), and x varies from 0 to 3.

In another aspect, supplying the semiconductor precursor and hydrogen in Step 1104 includes substeps. Step 1104a supplies power to a top electrode at a frequency in the range of 13.56 to 300 megahertz (MHz), and a power density of less than 10 watts per square centimeter (W/cm²). Step 1104b supplies power to a bottom electrode at a frequency in the range of 50 kilohertz to 13.56 MHz, and a power density of up to 3 W/cm². Step 1104c uses an atmosphere pressure in the range of 1 to 500 mTorr, and Step 1104d supplies an oxygen source gas. For example, N₂O, NO, O₂, or O₃ may be used. Then, forming the semiconductor nanoparticle embedded Si insulating film in Step 1108 includes forming a SiO_{X}N_{Y} thin-film. In a different aspect, Step 1104e supplies an inert noble gas. In another aspect, Step 1104 supplies a nitrogen source gas such as N₂ or NH₃.

Alternately, if Step 1104d supplies SiₙH₂ₙ₊₂ and a C source, then Step 1108 forms a SiC_{X} thin-film. The C source may be any suitable hydrocarbon-containing precursor. Some examples of hydrocarbon-containing precursors include alkanes (CₙH₂ₙ₊₂), alkenes (CₙH₂ₙ), alkynes (CₙH₂ₙ₋₂), Benzene (C₆H₆), and Toluene (C₇H₈).

In one aspect, following the formation of the semiconductor nanoparticle embedded Si insulating film, Step 1110 anneals by heating the substrate to a temperature of greater than about 400° C., for a time duration in the range of about 10 to 300 minutes, and in an atmosphere including oxygen and hydrogen. Optionally, the atmosphere may also include inert gases. Then, Step 1112 modifies the size of the semiconductor nanoparticles in the SiO_{X}N_{Y} thin-film in response to the annealing. The annealing process may use a heat source having a radiation wavelength in the range of about 150 to 600 nm, or in the range of about 9 to 11 micrometers.

In addition to, or as an alternative to the annealing process, Step 1114 performs a HD plasma treatment with the semiconductor nanoparticle embedded Si insulating film in an H₂ atmosphere, using a substrate temperature of less than 400° C. Step 1116 hydrogenates the semiconductor nanoparticle embedded Si insulating film.

More particularly, Step 1116 may include the following substeps. Step 1116a supplies power to a top electrode at a frequency in the range of 13.56 to 300 MHz, and a power density of up to 10 W/cm². Step 1116b supplies power to a bottom electrode at a frequency in the range of 50 kilohertz to 13.56 MHz, and a power density of up to 3 W/cm². Step 1116c uses an atmosphere pressure in the range of 1 to 500 mTorr, and Step 1116d supplies H₂ and an inert gas.

In a different aspect, Step 1109 optionally dopes the semiconductor nanoparticle embedded Si insulating film with a Type 3, Type 4, Type 5, or rare earth element dopant prior to a phase separation anneal in Step 1110. Alternately, Step 1113 dopes the semiconductor nanoparticle embedded Si insulating film after the phase separation annealing of Step 1110. The doping step can be executed before or after annealing. Annealing is typically required after doping to activate the dopants. Overall, annealing has two purposes: (1) to induce phase separation, and (2) activate the dopants. In response to doping, Step 1108 forms a semiconductor nanoparticle embedded Si insulating film with (modified) optical absorption or emission characteristics in the range of frequencies from deep ultraviolet (UV) to far infrared (IR). As noted above, the doping may be performed in-situ using a dopant source gas or physical sputtering source.

In addition to, or as an alternative to annealing, following the formation of the SiO_{X}N_{Y} thin-film, Step 1120 oxidizes the non-stoichiometric SiO_{X}N_{Y} thin-film using either a plasma or thermal oxidation process. Then, Step 1122 modifies the size of semiconductor nanoparticles in the SiO_{X}N_{Y} thin-film in response to the oxidation process.

Photodetectors have been described that are made with semiconductor nanoparticles embedded Si insulating films. Specific examples of SiO_{X1}N_{Y1} thin-films and SiO_{X1}N_{Y1} thin-film fabrication details have been presented. Some details of other specific materials and process details have also been used to illustrate the invention. However, the invention is not limited to merely these examples. Other variations and embodiments of the invention will occur to those skilled in the art.

We claim:

1. A photodetector employing a semiconductor nanoparticle embedded insulating film, the photodetector comprising:
a bottom electrode;
a semiconductor nanoparticle embedded Si insulating film overlying the bottom electrode, the insulating film including an element selected from a group consisting of N and C; and,
a transparent electrode overlying the insulating film.

2. The photodetector of claim 1 wherein the Si insulating film is a non-stoichiometric SiO_{X1}N_{Y1} thin-film overlying the bottom electrode, where (X1+Y1<2 and Y1>0).

3. The photodetector of claim 1 wherein the Si insulating film is a SiC_{X} thin film, where X<1.

4. The photodetector of claim 1 wherein the semiconductor nanoparticles embedded in the Si insulating film have a diameter in a range of about 1 to 10 nanometers (nm).

5. The photodetector of claim 1 wherein the semiconductor nanoparticles are a material selected from a group consisting of Si and Ge.

6. The photodetector of claim 1 wherein the bottom electrode is a material selected from a group consisting of a doped semiconductor, metal, and polymer.

7. The photodetector of claim 1 wherein the semiconductor nanoparticle embedded Si insulating film exhibits a spectral response in a wavelength range of about 200 nanometers (nm) to about 1600 nm.

8. A method for fabricating a semiconductor nanoparticle embedded Si insulating film for photo-detection applications, the method comprising:
providing a bottom electrode;
introducing a semiconductor precursor and hydrogen;
depositing a thin-film overlying the substrate, using a high density (HD) plasma-enhanced chemical vapor deposition (PECVD) process; and,
forming a semiconductor nanoparticle embedded Si insulating film including an element selected from a group consisting of N and C.

9. The method of claim 8 wherein the semiconductor nanoparticle embedded Si insulating film is a non-stoichiometric SiO_{X}N_{Y} thin-film, where (X+Y<2 and Y>0).

10. The method of claim 8 wherein the semiconductor nanoparticle embedded Si insulating film is SiC_{X}, where X<1.

11. The method of claim 8 wherein the semiconductor nanoparticles are a material selected from a group consisting of Si and Ge.

12. The method of claim 8 wherein depositing the thin film using an HD PECVD process includes using an inductively coupled plasma (ICP) source.

13. The method of claim 8 further comprising:
heating the substrate to a temperature of less than about 400° C.

14. The method of claim 8 wherein introducing the semiconductor precursor and hydrogen includes supplying a precursor selected from a group consisting of SiₙH2ₙ₊₂ and GeₙH₂ₙ₊₂, where n varies from 1 to 4, SiHₓR₄₋ₓ where R is selected from a first group consisting of Cl, Br, and I, and where x varies from 0 to 3, and GeHₓR₄₋ₓ where R is selected from the first group, and x varies from 0 to 3.

15. The method of claim 8 wherein depositing the thin-film using the HD PECVD process includes using a plasma concentration of greater than 1×10¹¹ cm⁻³, with an electron temperature of less than 10 eV.

16. The method of claim 8 wherein introducing the semiconductor precursor and hydrogen includes:
supplying power to a top electrode at a frequency in the range of 13.56 to 300 megahertz (MHz), and a power density of less than 10 watts per square centimeter (W/cm²);
supplying power to a bottom electrode at a frequency in the range of 50 kilohertz to 13.56 MHz, and a power density of up to 3 W/cm²;
using an atmosphere pressure in the range of 1 to 500 mTorr; and,
supplying an oxygen source gas; and,
wherein forming the semiconductor nanoparticle embedded Si insulating film includes forming a SiO_{X}N_{Y} thin-film.

17. The method of claim 16 wherein supplying the oxygen source gas includes supplying an oxygen source gas selected from a group consisting of N₂O, NO, O₂, and O₃.

18. The method of claim 17 wherein introducing the semiconductor precursor and hydrogen includes supplying an inert noble gas.

19. The method of claim 16 wherein introducing the semiconductor precursor and hydrogen includes supplying a nitrogen source gas, selected from a group consisting of N₂ and NH₃.

20. The method of claim 8 further comprising:
following the formation of the semiconductor nanoparticle embedded Si insulating film, annealing as follows:
heating the substrate to a temperature of greater than about 400° C.;
heating for a time duration in the range of about 10 to 300 minutes;
heating in an atmosphere selected from a group consisting of oxygen and hydrogen, and oxygen, hydrogen, and inert gases; and,
modifying the size of the semiconductor nanoparticles in the Si insulating film in response to the annealing.

21. The method of claim 8 further comprising:
following the formation of the semiconductor nanoparticle embedded Si insulating film, annealing using a heat source having a radiation wavelength selected from a group consisting of about 150 to 600 nanometers (nm) and 9 to 11 micrometers.

22. The method of claim 8 further comprising:
performing a HD plasma treatment with the semiconductor nanoparticle embedded Si insulating film in an H₂ atmosphere, using a substrate temperature of less than 400° C.; and,
hydrogenating the semiconductor nanoparticle embedded Si insulating film.

23. The method of claim 22 wherein hydrogenating the semiconductor nanoparticle embedded Si insulating film using the HD plasma process includes:
supplying power to a top electrode at a frequency in the range of 13.56 to 300 MHz, and a power density of up to 10 W/cm²;
supplying power to a bottom electrode at a frequency in the range of 50 kilohertz to 13.56 MHz, and a power density of up to 3 W/cm²;
using an atmosphere pressure in the range of 1 to 500 mTorr; and,
supplying H₂ and an inert gas.

24. The method of claim 8 further comprising:
doping the semiconductor nanoparticle embedded Si insulating film with a dopant selected from a group consisting of Type 3, Type 4, Type 5, and rare earth elements; and,
in response to doping, forming a semiconductor nanoparticle embedded Si insulating film with optical absorption characteristics in a range of frequencies from deep ultraviolet (UV) to far infrared (IR).

25. The method of claim 9 further comprising:
following the formation of the SiO_{X}N_{Y} thin-film, oxidizing the non-stoichiometric SiO_{X}N_{Y} thin-film using a process selected from a group consisting of plasma and thermal oxidation; and,
modifying the size of semiconductor nanoparticles in the SiO_{X}N_{Y} thin-film in response to the oxidation process.

26. The method of claim 9 wherein forming the SiO_{X}N_{Y} thin-film includes forming a non-stoichiometric SiO_{X}N_{Y} thin-film with values of X and Y that vary with respect to the thickness of the thin-film.

27. The method of claim 8 wherein depositing the thin film includes using the HD PECVD process includes:
supplying power to a top electrode at a frequency in the range of 13.56 to 300 MHz, and a power density of less than 10 W/Cm²;
supplying power to a bottom electrode at a frequency in the range of 50 kilohertz to 13.56 MHz, and a power density of up to 3 W/cm²;
using an atmosphere pressure in the range of 1 to 500 mTorr; and,
supplying SiₙH₂ₙ₊₂ and a C source; and,
wherein forming the semiconductor nanoparticle embedded Si insulating film includes forming a SiC_{X} thin-film.
